(19) United States
(12) Patent Application Publication
(10) Pub. No.: US 2021/0273206 A1
(43) Pub. Date: Sep. 2, 2021

(54) METHOD FOR AVOIDING WARPING OF SUBSTRATE, METHOD FOR MANUFACTURING DISPLAY PANEL, AND DISPLAY PANEL

(71) Applicant: BOE TECHNOLOGY GROUP CO., LTD., Beijing (CN)

(72) Inventor: Chunjing HU, Beijing (CN)

(73) Assignee: BOE TECHNOLOGY GROUP CO., LTD., Beijing (CN)

(21) Appl. No.: 17/262,521

(22) PCT Filed: May 18, 2020
(86) PCT No.: PCT/CN2020/090820

§ 371 Date: Jan. 22, 2021

(30) Foreign Application Priority Data
Jun. 13, 2019 (CN) 201910511159.2

(51) Int. Cl. H01L 51/56; H01L 51/00; B05D 7/00; C08J 7/043

(52) U.S. Cl. CPC H01L 51/56; H01L 51/0001; H01L 2251/566; C08J 7/043; B05D 2505/50; B05D 7/542

(57) ABSTRACT

A method for avoiding warping of a substrate, a method for manufacturing a display panel, and a display panel. The method for avoiding warping of a substrate includes: providing a substrate, forming an amphiphilic material layer on the substrate, and forming a polyimide layer on the amphiphilic material layer, the amphiphilic material layer being at least located below an edge portion of the polyimide layer, and a curing temperature of the polyimide layer being higher than a critical solution temperature of the amphiphilic material layer.

### CROSS REFERENCES TO RELATED APPLICATIONS

The present application claims the priority of Chinese Patent Application No. 201910511159.2 filed on Jun. 13, 2019, and entitled “Method of Avoiding Warpage and Stabilizing Polyimide Substrate and Method of Manufacturing Display Panel”, which is incorporated herein by reference in its' entirety for all purposes.

### TECHNICAL FIELD

Embodiments of the present disclosure relate to a method for avoiding warping of a substrate, a method for manufacturing a display panel, and a display panel.

### BACKGROUND

In an initial stage of a preparation process of a flexible substrate, polyimide (PI) adhesive is required to be coated on a substrate, and then the polyimide adhesive is heated and cured to form a polyimide layer. When the polyimide layer is formed by heating and curing, the polyimide layer tends to shrink. A shrinkage strength of the polyimide layer is greater than a shrinkage strength of the substrate, and the edge of the polyimide layer shrinks to drive the substrate to shrink towards the middle portion, such that the edge of the substrate to warp. After this kind of warpage is formed, the warpage can affect the accuracy of manufacturing a device in the subsequent processes, and also can damage a film forming equipment.

### SUMMARY

Embodiments of the present disclosure provide a method for avoiding warpage of a substrate, a method of manufacturing a display panel, and a display panel.

At least one embodiment of the present disclosure provides a method for avoiding warping of a substrate, comprising: providing a substrate; forming an amphiphilic material layer on the substrate; and forming a polyimide layer on the amphiphilic material layer. The amphiphilic material layer is at least located between an edge portion of the polyimide layer and an edge portion of the substrate, and a curing temperature of the polyimide layer is higher than a critical dissolution temperature of the amphiphilic material layer.

For example, the amphiphilic material layer has a thickness less than about 20 nanometers.

For example, the amphiphilic material layer is formed below the entire polyimide layer, and an orthographic projection of the amphiphilic material layer on the substrate completely covers an orthographic projection of the polyimide layer on the substrate.

For example, the amphiphilic material layer comprises material selected from a group consisting of poly(N-isopropylacrylamide), polystyrene-polyisoprene, polyoxyethylene-polyoxypropylene, polyisobutylene-polydimethylsiloxane, copolymer of acryloyl glycine amide and acrylonitrile, and polydimethylaminopropyl methacrylamide-b-[poly-2-(2-methoxyethoxy)ethyl methacrylate-co-polyethylene glycol methacrylate].

For example, the critical dissolution temperature of the amphiphilic material layer is from about 30° C. to about 100° C.

For example, the forming the polyimide layer on the amphiphilic material layer comprises: applying a polyimide adhesive on the amphiphilic material layer; and heating and curing the polyimide adhesive, and a temperature of heating and curing is about 100° C. to about 230° C.

For example, in the process of heating the polyimide adhesive, amphiphilic substance in the amphiphilic material layer is lyophobicity, and a slippage occurs between a shrinkage portion of the polyimide layer and the substrate.

For example, a temperature of heating and curing is from about 100° C. to about 230° C.

At least one embodiment of the present disclosure also provides a method for manufacturing a display panel, comprising any of the methods for avoiding warping of the substrate, and further comprising: forming at least one functional layer on the polyimide layer.

For example, forming a light-emitting layer.

For example, forming an Indium Tin Oxide layer, a display layer, a cathode layer, etc.

At least one embodiment of the present disclosure also provides a display panel, comprising: a polyimide substrate, an anti-warpage structure, and at least one functional layer. The anti-warpage structure is configured to make an edge position of the polyimide substrate flat and un-curling, which makes the at least one functional layer above the anti-warping structure flat and un-curling at the edge position of the polyimide substrate.

For example, the polyimide substrate comprises a substrate, a polyimide layer and an amphiphilic material layer between the substrate and the polyimide layer, the amphiphilic material layer is at least located between an edge portion of the polyimide layer and an edge portion of the substrate, a curing temperature of the polyimide layer is higher than a critical dissolution temperature of the amphiphilic material layer, and the polyimide layer is the anti-warpage structure.

For example, the amphiphilic material layer has a thickness less than about 20 nanometers.

For example, the amphiphilic material layer is formed below the entire polyimide layer, and an orthographic projection of the amphiphilic material layer on the substrate completely covers an orthographic projection of the polyimide layer on the substrate.

For example, the amphiphilic material layer comprises material selected from a group consisting of poly(N-isopropylacrylamide), polystyrene-polyisoprene, polyoxyethylene-polyoxypropylene, polyisobutylene-polydimethylsiloxane, copolymer of acryloyl glycine amide and acrylonitrile, and polydimethylaminopropyl methacrylamide-b-[poly-2-(2-methoxyethoxy)ethyl methacrylate-co-polyethylene glycol methacrylate].

For example, the critical dissolution temperature of the amphiphilic material layer is from about 30° C. to about 100° C.

For example, the display panel further comprises a light-emitting function layer on the polyimide layer.

### BRIEF DESCRIPTION OF THE DRAWINGS

Embodiments of the present disclosure will be described in more detail below with reference to accompanying drawings to allow an ordinary skill in the art to more clearly understand embodiments of the present disclosure, in which:

FIG. 1 is a flowchart of a method for avoiding warping of a substrate provided by an embodiment of the present disclosure;

FIG. 2 is a schematically structure diagram implemented by a method for avoiding warping of a substrate according to an embodiment of the present disclosure;

FIG. 3 is another schematically structural diagram implemented by a method for avoiding warping of a substrate according to an embodiment of the present disclosure.

### DETAILED DESCRIPTION

The technical solutions of the embodiments will be described in a clearly and fully understandable way in connection with the related drawings. It is apparent that the described embodiments are just a part but not all of the embodiments of the present disclosure. Based on the described embodiments herein, those skilled in the art can obtain, without any inventive work, other embodiment(s) which shall be within the scope of the present disclosure.

Unless otherwise defined, all the technical and scientific terms used herein have the same meanings as commonly understood by one of ordinary skill in the art to which the present disclosure belongs. The terms, such as “first,” “second,” or the like, which are used in the present application, are not intended to indicate any sequence, amount or importance, but for distinguishing various components. Also, the terms, such as “comprise/comprising,” “include/including,” or the like are intended to specify that the elements or the objects stated before these terms encompass the elements or the objects and equivalents thereof listed after these terms, but not preclude other elements or objects. The terms, “on,” “under,” or the like are only used to indicate relative position relationship, and when the absolute position of the object which is described is changed, the relative position relationship may be changed accordingly.

In the present disclosure, the same or similar reference signs indicate the same or the similar elements or elements with the same or the similar functions. The embodiments described below with reference to the drawings are exemplary, which are only used to explain the present disclosure and cannot be understood as a limitation to the present disclosure.

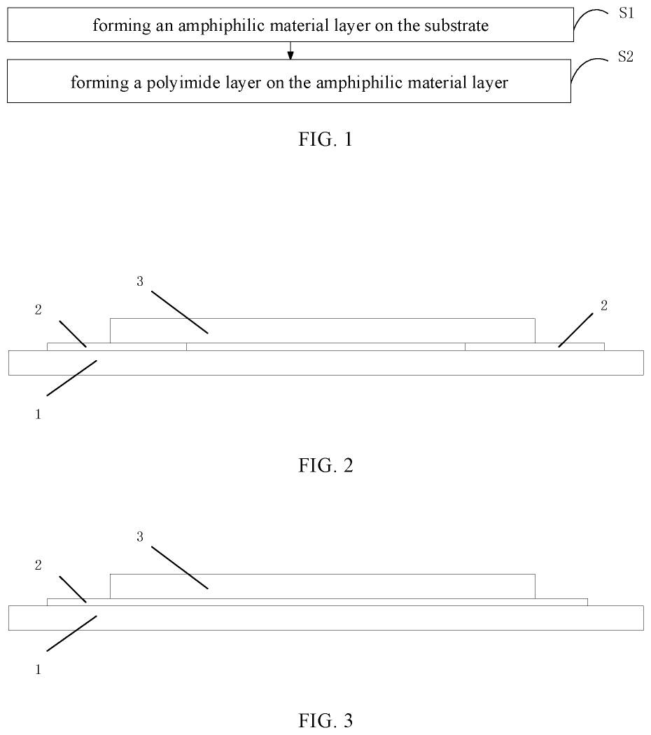

As illustrated in FIG. 1, the embodiment of the present disclosure provides a method for preventing a substrate warping, which includes following steps:

S1: forming an amphiphilic material layer on a substrate;

For example, the substrate is, but not limited to, a glass substrate. For example, the substrate may also be a plastic substrate or a quartz substrate.

For example, the amphiphilic material layer is formed on the substrate by coating. A molecule of an amphiphilic material that forms the amphiphilic material layer has both a lyophilic group and a lyophobicity group, in a case that a temperature is lower than a critical dissolution temperature of the amphiphilic material layer, the lyophilic group in a macromolecule of the material interacts with a water molecule, due to the effect of hydrogen bonds and van der Waals force, the water molecules around the macromolecules form a solvated shell layer connected by the hydrogen bonds, which makes the macromolecule exhibit an extended coil structure and exhibit a lyophilic property; while in a case that the temperature rises, the hydrogen bonds between the lyophilic groups and the liquid are broken, then the solvated shell layer is destroyed, which exhibits a lyophobicity property, and the coil structure becomes a compact colloidal structure, then the temperature response is achieved through a conformation of coil or the colloidal of a whole macromolecular.

S2: forming a polyimide layer on the amphiphilic material layer. For example, the amphiphilic material layer is at least located below an edge portion of the polyimide layer, and the curing temperature of the polyimide layer is higher than the critical dissolution temperature of the amphiphilic material layer.

Because the amphiphilic material layer is formed between the substrate and the polyimide layer, in a case that the polyimide layer is heated and cured, with the temperature rises, in a case that the temperature is higher than the critical dissolution temperature of the amphiphilic material layer, the amphiphilic substance in the amphiphilic material layer is lyophobicity. In this way, an edge shrinkage of the polyimide layer occurs on the amphiphilic material layer which is lyophobicity, and a certain amount of slippage is generated between the shrinkage portion of the polyimide layer and the substrate, which overcomes the problem that the shrinkage portion of the polyimide layer pulls the substrate to warp due to the adhesion with bonding strength between the polyimide layer and the substrate. In the case of no warping of the substrate, the accuracy of manufacturing the device in the subsequent processes can be realized, and the film forming equipment will not be damaged.

As illustrated in FIG. 2, for example, the amphiphilic material layer 2 is only formed below the edge portion of the polyimide layer 3, and the amphiphilic material layer 2 is not formed below the middle portion of the polyimide layer 3. For example, the amphiphilic material layer 2 is coated on the substrate 1 to reduce an amount of the amphiphilic material used in the amphiphilic material layer 2.

For example, in a case that the above-mentioned structure that the amphiphilic material layer is only formed below the edge portion of the polyimide layer is adopted, in order to prevent the amphiphilic material layer from having a great effect on the thickness of the polyimide layer, the amphiphilic material layer has a thickness less than about 20 nanometers. For example, the thickness of the amphiphilic material layer fluctuates in a range of 20±2 nanometers.

For example, as illustrated in FIG. 3, the amphiphilic material layer 2 is formed below the entire polyimide layer 3. That is, the polyimide layer 3 is entirely located on the amphiphilic material layer 2, and the amphiphilic material layer 2 is applied on the substrate 1. For example, an orthographic projection of the amphiphilic material layer on the substrate completely covers an orthographic projection of the polyimide layer on the substrate, or the orthographic projection of the amphiphilic material layer on the substrate overlaps the orthographic projection of the polyimide layer on the substrate. In this structure, the thickness of the amphiphilic material layer may not be limited.

Further, for example, the amphiphilic material layer comprises material selected from a group consisting of poly(N-isopropylacrylamide), polystyrene-polyisoprene, polyoxyethylene-polyoxypropylene, polyisobutylene-polydimethylsiloxane, copolymer of acryloyl glycine amide and acrylonitrile, and polydimethylaminopropyl methacrylamide-b-[poly-2-(2-methoxyethoxy)ethyl methacrylate-co-polyethylene glycol methacrylate].

Further, for example, the critical dissolution temperature of the amphiphilic material layer is from about 30° C. to about 100° C. For example, the critical dissolution temperature of the amphiphilic material layer fluctuates within a range of 10% above and below the end values of the above temperature values. For example, two monomers having different critical temperatures are copolymerized according to a certain proportion to form the above-mentioned materials to adjust the critical dissolution temperature range of a polymer.

Further, for example, the forming the polyimide layer on the amphiphilic material layer includes following operations.

Coating a polyimide adhesive on the amphiphilic material layer.

The coating of the polyimide adhesive can be carried out at room temperature, and the critical dissolution temperature of the amphiphilic material layer is from about 30° C. to about 100° C., which is higher than the room temperature, at this time, the amphiphilic material layer is lyophilic, and the polyimide adhesive can be successfully coated on the amphiphilic material layer.

Heating and curing the polyimide adhesive. The temperature of heating and curing is about 100° C. to about 230° C. For example, the temperature of heating and curing fluctuates within a range of 10% above and below the end values of the above temperature values.

The temperature of heating and curing is higher than the critical dissolution temperature of the amphiphilic material layer, at this time, the amphiphilic material layer appears to be lyophobic, and the polyimide layer shrinks on the lyophobic material, which will not drive the substrate to shrink and thus prevent the substrate from warping.

The embodiment of the present disclosure also provides a method of manufacturing a display panel, which includes the method for avoiding warping of the substrate in the above-mentioned embodiments, and further includes forming a light-emitting layer on the polyimide layer.

The steps of forming the light-emitting layer and the structure of the light-emitting layer can refer to related technologies, which are omitted herein. For example, the forming the light-emitting layer includes, but not limited to, forming an ITO (Indium Tin Oxide) layer, a display layer and a cathode layer, and so on.

The following points should be noted:

1) The accompanying drawings involve only the structure(s) in connection with the embodiment(s) of the present disclosure, and other structure(s) can be referred to common design(s).

2) Without conflicting with each other, features in one embodiment or in different embodiments can be combined to obtain new embodiment(s), the new embodiment(s) shall also belong the scope of the present disclosure.

The described above is only the exemplary embodiments of the present disclosure, and the scope of the present disclosure is not limited thereto. A person of ordinary skill in the art can make various changes and modifications without departing from the technical scope of the embodiments of the present disclosure, and such changes and modifications shall fall into the scope of the present disclosure.

1. A method for avoiding warping of a substrate, comprising:
providing a substrate;
forming an amphiphilic material layer on the substrate; and
forming a polyimide layer on the amphiphilic material layer, wherein the amphiphilic material layer is at least located between an edge portion of the polyimide layer and an edge portion of the substrate, and a curing temperature of the polyimide layer is higher than a critical dissolution temperature of the amphiphilic material layer.

2. The method for avoiding warping of the substrate according to claim 1, wherein the amphiphilic material layer has a thickness less than about 20 nanometers.

3. The method for avoiding warping of the substrate according to claim 1, wherein the amphiphilic material layer is formed below the entire polyimide layer, and an orthographic projection of the amphiphilic material layer on the substrate completely covers an orthographic projection of the polyimide layer on the substrate.

4. The method for avoiding warping of the substrate according to claim 1, wherein the amphiphilic material layer comprises material selected from a group consisting of poly(N-isopropylacrylamide), polystyrene-polyisoprene, polyoxyethylene-polyoxypropylene, polyisobutylene-polydimethylsiloxane, copolymer of acryloyl glycine amide and acrylonitrile, and polydimethylaminopropyl methacrylamide-b-[poly-2-(2-methoxyethoxy)ethyl methacrylate-co-polyethylene glycol methacrylate].

5. The method for avoiding warping of the substrate according to claim 1, wherein the critical dissolution temperature of the amphiphilic material layer is from about 30° C. to about 100° C.

6. The method for avoiding warping of the substrate according to claim 1, wherein the forming the polyimide layer on the amphiphilic material layer comprises:
applying a polyimide adhesive on the amphiphilic material layer; and
heating and curing the polyimide adhesive, wherein a temperature of heating and curing is about 100° C. to about 230° C.

7. The method for avoiding warping of the substrate according to claim 5, wherein in the process of heating the polyimide adhesive, amphiphilic substance in the amphiphilic material layer is lyophobicity, and a slippage occurs between a shrinkage portion of the polyimide layer and the substrate.

8. The method for avoiding warping of the substrate according to claim 1, wherein a temperature of heating and curing is from about 100° C. to about 230° C.

9. A method for manufacturing a display panel, comprising:
providing a substrate;
forming an amphiphilic material layer on the substrate;
forming a polyimide layer on the amphiphilic material layer, wherein the amphiphilic material layer is at least located between an edge portion of the polyimide layer and an edge portion of the substrate, and a curing temperature of the polyimide layer is higher than a critical dissolution temperature of the amphiphilic material layer; and
forming at least one functional layer on the polyimide layer.

10. The method for manufacturing the display panel according to claim 9, further comprising:
forming a light-emitting layer.

11. The method for manufacturing the display panel according to claim 9, further comprising:
forming an Indium Tin Oxide layer, a display layer, a cathode layer, etc.

12. A display panel, comprising: a polyimide substrate, an anti-warpage structure, and at least one functional layer, wherein the anti-warpage structure is configured to make an edge position of the polyimide substrate flat and un-curling, which makes the at least one functional layer above the anti-warping structure flat and un-curling at the edge position of the polyimide substrate.

13. The display panel according to claim 12, wherein the polyimide substrate comprises a substrate, a polyimide layer and an amphiphilic material layer between the substrate and the polyimide layer, the amphiphilic material layer is at least located between an edge portion of the polyimide layer and an edge portion of the substrate, a curing temperature of the polyimide layer is higher than a critical dissolution temperature of the amphiphilic material layer, and the polyimide layer is the anti-warpage structure.

14. The display panel according to claim 13, wherein the amphiphilic material layer has a thickness less than about 20 nanometers.

15. The display panel according to, wherein the amphiphilic material layer is provided below the entire polyimide layer, and an orthographic projection of the amphiphilic material layer on the substrate completely covers an orthographic projection of the polyimide layer on the substrate.

16. The display panel according to claim 13, wherein the amphiphilic material layer comprises material selected from a group consisting of poly(N-isopropylacrylamide), polystyrene-polyisoprene, polyoxyethylene-polyoxypropylene, polyisobutylene-polydimethylsiloxane, copolymer of acryloyl glycine amide and acrylonitrile, and polydimethylaminopropyl methacrylamide-b-[poly-2-(2-methoxyethoxy)ethyl methacrylate-co-polyethylene glycol methacrylate].

17. The display panel according to claim 13, wherein the critical dissolution temperature of the amphiphilic material layer is from about 30° C. to about 100° C.

18. The display panel according to claim 12, further comprising a light-emitting function layer on the polyimide layer.

19. The method for avoiding warping of the substrate according to claim 2, wherein the amphiphilic material layer is formed below the entire polyimide layer, and an orthographic projection of the amphiphilic material layer on the substrate completely covers an orthographic projection of the polyimide layer on the substrate.

20. The method for avoiding warping of the substrate according to claim 19, wherein the amphiphilic material layer comprises material selected from a group consisting of poly(N-isopropylacrylamide), polystyrene-polyisoprene, polyoxyethylene-polyoxypropylene, polyisobutylene-polydimethylsiloxane, copolymer of acryloyl glycine amide and acrylonitrile, and polydimethylaminopropyl methacrylamide-b-[poly-2-(2-methoxyethoxy)ethyl methacrylate-co-polyethylene glycol methacrylate];
the critical dissolution temperature of the amphiphilic material layer is from about 30° C. to about 100° C.;
wherein the forming the polyimide layer on the amphiphilic material layer comprises:
applying a polyimide adhesive on the amphiphilic material layer; and
heating and curing the polyimide adhesive, wherein a temperature of heating and curing is about 100° C. to about 230° C.
